(19) United States
(12) Patent Application Publication
(10) Pub. No.: US 2025/0120286 A1
(43) Pub. Date: Apr. 10, 2025

(54) DISPLAY APPARATUS AND METHOD OF MANUFACTURING THE SAME

(71) Applicant: Samsung Display Co., LTD., Yongin-si (KR)

(72) Inventors: Kukbin LIM, Yongin-si (KR); Hyeonji KIM, Yongin-si (KR); Soonnyung PARK, Yongin-si (KR)

(21) Appl. No.: 18/751,210

(22) Filed: Jun. 22, 2024

(30) Foreign Application Priority Data
Oct. 4, 2023 (KR) 10-2023-0131931

(51) Int. Cl. H10K 59/80; H10K 102/00

(52) U.S. Cl. CPC H10K 59/871; H10K 2102/311

(57) ABSTRACT

A method of manufacturing a display apparatus includes: providing a display panel including a first panel area, a second panel area, and a panel bending area between the first panel area and the second panel area; providing a printed circuit board (PCB) to which a preliminary PCB adhesive layer and a release film are attached; bonding the PCB to the second panel area; and forming a PCB adhesive layer by removing the release film from the PCB. In the providing of the PCB, the release film is attached to the PCB through a release film adhesive layer between the release film and the PCB, the preliminary PCB adhesive layer includes a first portion and a second portion other than the first portion, the first portion corresponds to the PCB adhesive layer, and the release film adhesive layer is attached to the second portion.

This application claims priority to Korean Patent Application No. 10-2023-0131931, filed on Oct. 4, 2023, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same, and more particularly, to a display apparatus with a reduced possibility of occurrence of defects in a manufacturing process, and a method of manufacturing the display apparatus.

### 2. Description of the Related Art

Display apparatuses may be used as various electronic apparatuses. For example, a display apparatus may be a mobile electronic apparatus such as a smartphone. In order to increase the area of a display surface while reducing the overall size of an electronic apparatus, the electronic apparatus may be a foldable electronic apparatus having a display surface that is partially folded.

Moreover, the display apparatus may receive information about images and provide images by using display elements of a display panel. In order to receive the information about images, pads electrically connected to the display elements may be arranged on an edge of the display panel, and the pads may be electrically connected to bumps of a printed circuit board. In order to minimize the area of a visible non-display area, the display panel may be bent such that a portion of the display panel and the printed circuit board overlap another portion of the display panel, and then, the printed circuit board may be attached to the other portion of the display panel.

### SUMMARY

In such display apparatuses of the related art, when an adhesive layer is formed to attach a printed circuit board to a display panel, by-products protruding outside of the adhesive layer may be generated, and these by-products may cause post-process defects and appearance defects.

One or more embodiments include a display apparatus with a reduced probability of defects in a manufacturing process and a method of manufacturing the display apparatus. However, the embodiments are examples, and do not limit the scope of the disclosure.

Additional aspects will be set forth in part in the description which follows and, in part, will be apparent from the description, or may be learned by practice of the presented embodiments of the disclosure.

According to one or more embodiments, a method of manufacturing a display apparatus includes: providing a display panel including a first panel area, a second panel area, and a panel bending area between the first panel area and the second panel area, where a metal plate is attached under the first panel area of the display panel; providing a printed circuit board to which a preliminary printed circuit board adhesive layer and a release film are attached; bonding the printed circuit board to the second panel area; forming a printed circuit board adhesive layer by removing the release film from the printed circuit board; and attaching the printed circuit board under the metal plate by bending the panel bending area. In the providing of the printed circuit board, the release film is attached to the printed circuit board through a release film adhesive layer between the release film and the printed circuit board, the preliminary printed circuit board adhesive layer includes a first portion and a second portion other than the first portion, the first portion corresponding to the printed circuit board adhesive layer, and the release film adhesive layer is attached to the second portion.

The forming of the printed circuit board adhesive layer may include removing the release film adhesive layer from the printed circuit board by removing the release film from the printed circuit board.

The forming of the printed circuit board adhesive layer may further include, when the release film adhesive layer is removed from the printed circuit board, removing the second portion, which is attached to the release film adhesive layer.

The first portion and the second portion may include the same material as each other.

The first portion may include a first conductive adhesive layer, a second conductive adhesive layer, and a conductive nonwoven layer between the first conductive adhesive layer and the second conductive adhesive layer, and the second portion and the conductive nonwoven layer may include the same material as each other.

In the providing of the printed circuit board, the first conductive adhesive layer of the preliminary printed circuit board adhesive layer may be attached to the printed circuit board.

In the providing of the printed circuit board, the release film adhesive layer and the printed circuit board adhesive layer may be arranged on the same surface of the printed circuit board.

In the providing of the printed circuit board, in a plan view, the release film adhesive layer may be arranged to be spaced apart from the first portion.

In the providing of the printed circuit board, in a plan view, at least a portion of the release film adhesive layer may be arranged along an outside of the first portion to surround at least a portion of the first portion.

In the providing of the printed circuit board, in a plan view, the preliminary printed circuit board adhesive layer may be arranged along an outer portion of the printed circuit board to surround at least a portion of the printed circuit board.

The attaching of the printed circuit board may include attaching the printed circuit board adhesive layer under the metal plate.

According to one or more embodiments, a display apparatus includes: a display panel including a first panel area, a second panel area, and a panel bending area between the first panel area and the second panel area; a metal plate arranged under the first panel area; a printed circuit board bonded to the second panel area and arranged under the metal plate; a printed circuit board adhesive layer between the printed circuit board and the metal plate; and a residual adhesive layer arranged on one surface of the printed circuit board in contact with the printed circuit board adhesive layer, where, in a plan view, the residual adhesive layer is arranged to be spaced apart from the printed circuit board adhesive layer.

In a plan view, at least a portion of the residual adhesive layer may be arranged along an outside of the printed circuit board adhesive layer to surround at least a portion of the printed circuit board adhesive layer.

In a plan view, the printed circuit board adhesive layer may be arranged along an outer portion of the printed circuit board to surround at least a portion of the printed circuit board.

The first panel area may include a first non-folding area, a second non-folding area, and a foldable area between the first non-folding area and the second non-folding area, and the display apparatus may be foldable at the foldable area.

The printed circuit board adhesive layer may include a first conductive adhesive layer, a second conductive adhesive layer, and a conductive nonwoven layer between the first conductive adhesive layer and the second conductive adhesive layer.

The first conductive adhesive layer may be between the printed circuit board and the conductive nonwoven layer, and the second conductive adhesive layer may be between the conductive nonwoven layer and the metal plate.

The conductive nonwoven layer may include a void.

The display apparatus may further include a lower protective layer arranged under the display panel, and a support layer between the lower protective layer and the metal plate.

The display apparatus may further include a cover window arranged over the display panel, and an upper protective layer between the display panel and the cover window.

Other aspects, features, and advantages of the disclosure will become more apparent from the detailed description, the claims, and the drawings.

### BRIEF DESCRIPTION OF THE DRAWINGS

The above and other aspects, features, and advantages of embodiments of the present disclosure will be more apparent from the following description taken in conjunction with the accompanying drawings, in which:

FIG. 1 is a schematic perspective view of a display apparatus in an unbent state, according to an embodiment;

FIG. 2 is a schematic perspective view of a display apparatus according to an embodiment;

FIG. 3 is a schematic plan view of a display panel included in a display apparatus, according to an embodiment;

FIG. 4 is a schematic cross-sectional view of a display apparatus in an unbent state, according to an embodiment;

FIG. 5 is a schematic cross-sectional view of a display apparatus according to an embodiment;

FIG. 6 is a schematic rear view of a display apparatus according to an embodiment;

FIG. 7 is a micrograph of a conductive nonwoven fabric layer included in a display apparatus, according to an embodiment;

FIG. 8 is a schematic enlarged cross-sectional view of an area A of the display apparatus of FIG. 5;

FIG. 9 is an equivalent circuit diagram of one pixel of the display panel of FIG. 3;

FIG. 10 is a schematic cross-sectional view of a display panel included in a display apparatus, according to an embodiment; and

FIGS. 11 to 16 are diagrams for describing a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because various modifications may be applied and one or more embodiments may be implemented, specific embodiments will be shown in the drawings and described in detail in the detailed description. Effects and features, and methods for achieving them will be clarified with reference to embodiments described below in detail with reference to the drawings. However, the embodiments may have different forms and should not be construed as being limited to the descriptions set forth herein.

It will be understood that although terms “first” and “second” may be used herein to describe various elements, these elements should not be limited by these terms and these terms are only used to distinguish one element from another.

As used herein, the singular forms include the plural forms unless the context clearly indicates otherwise.

It will be understood that terms “comprise,” “include,” and “have” may be used herein to specify the presence of stated features or elements, but do not preclude the presence or addition of one or more other features or elements.

In the present specification, it will be understood that when an element, such as a layer, film, region, or plate, is referred to as being “on” another element, the element may be “directly on” the other element or indirectly on the other element with intervening elements therebetween.

It will be understood that when a layer, region, or element is referred to as being “connected to” another layer, region, or element, it may be “directly connected to” the other layer, region, or element or may be “indirectly connected to” the other layer, region, or element with one or more intervening layers, regions, or elements therebetween. For example, it will be understood that when a layer, region, or element is referred to as being “electrically connected to” another layer, region, or element, it may be “directly electrically connected to” the other layer, region, or element and/or may be “indirectly electrically connected to” the other layer, region, or element with one or more intervening layers, regions, or elements therebetween.

In the present specification, the x-axis, the y-axis, and the z-axis are not limited to three axes of the rectangular coordinate system and may be interpreted in a broader sense. For example, the x-axis, y-axis, and z-axis may be orthogonal to each other, but may refer to different directions that are not orthogonal to each other.

In the present specification, when a certain embodiment may be implemented differently, a specific process order may also be performed differently from the described order. As an example, two processes that are successively described may be performed substantially simultaneously or performed in an order opposite to the order described.

When the expression “on a plane” or “in a plan view” is used herein, it may refer to when a target area is seen from above. That is, the expression “on a plane” or “in a plan view” used herein may refer to “when seen in a direction (z direction) perpendicular to a substrate 100.”

Hereinafter, the embodiments will now be described in detail with reference to the accompanying drawings. When described with reference to the drawings, identical or corresponding elements will be given the same reference numerals, and repeated descriptions of these elements will be omitted. Sizes of elements in the drawings may be exaggerated for convenience of description. For example, because sizes and thicknesses of elements in the drawings are arbitrarily illustrated for convenience of explanation, the following embodiments are not limited thereto.

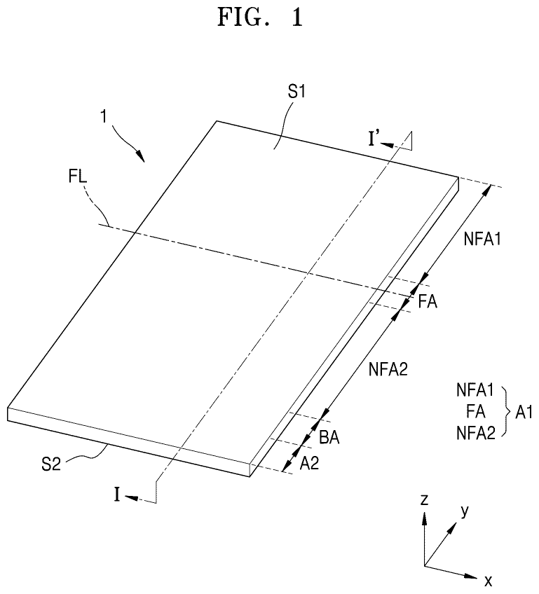

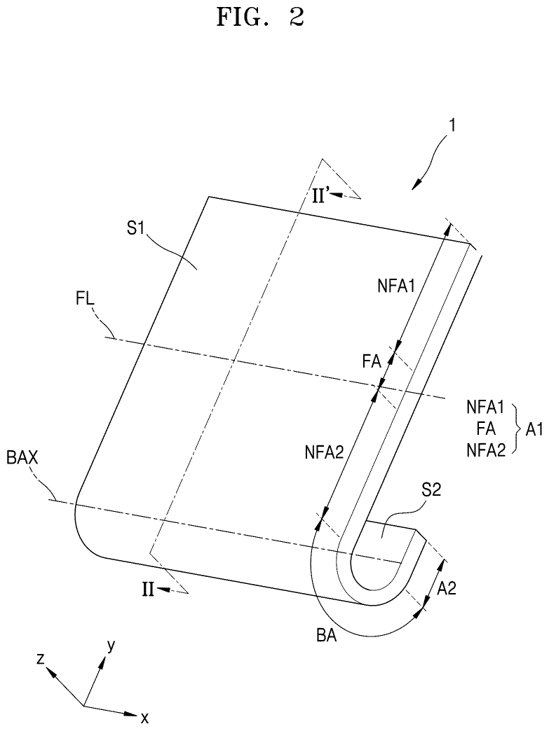

FIG. 1 is a schematic perspective view of a display apparatus 1 in an unbent state, according to an embodiment. FIG. 2 is a schematic perspective view of the display apparatus 1 according to an embodiment. That is, FIG. 2 shows a state in which the display apparatus 1 of FIG. 1 is bent.

As shown in FIGS. 1 and 2, the display apparatus 1 may include a first area A1, a second area A2, and a bending area BA between the first area A1 and the second area A2. In detail, the display apparatus 1 may include the first area A1, the bending area BA outside the first area A1, and the second area A2 arranged on the opposite side of the first area A1 with respect to the bending area BA.

The first area A1 may include a display area and a non-display area, and the second area A2 may include only a non-display area. As shown in FIG. 2, the display apparatus 1 is bent in the bending area BA, and accordingly, when seen in a z-axis direction, at least a portion of the second area A2 may overlap the first area A1. In detail, the display apparatus 1 may be bent in the bending area BA with respect to a bending axis BAX extending in a first direction (e.g., a +x direction or −x direction). Because the display apparatus 1 is bent in the bending area BA, when the display apparatus 1 is seen in a −z direction, a portion of the non-display area may be prevented from being visible. Accordingly, the area of a visible non-display area may be significantly reduced.

The display apparatus 1 may include a first surface S1 and a second surface S2 that is opposite to the first surface S1. The display apparatus 1 may display an image on the first surface S1. That is, the first surface S1 of the display apparatus 1 may include a display surface. In detail, the first surface S1 of the first area A1 of the display apparatus 1 may include a display surface. As the display apparatus 1 is bent in the bending area BA, the second surface S2 of the first area A1 and the second surface S2 of the second area A2 may be arranged to face each other.

In addition, as shown in FIGS. 1 and 2, the first area A1 may include a first non-folding area NFA1, a second non-folding area NFA2, and a foldable area FA. At least a portion of the display apparatus 1 may be flexible, and as the flexible portion of the display apparatus 1 is bent, the display apparatus 1 may be folded. Accordingly, the display apparatus 1 may include a folding area and a non-folding area that is provided on at least one side of the folding area and is not folded. As used herein, “non-folding” means that a portion is not folded, and this includes a case where the portion is not flexible and hard and thus is not folded, and a case where the portion is flexible but not folded. The first non-folding area NFA1 and the second non-folding area NFA2 may be non-folding areas, and the foldable area FA may be an area that is flexible and foldable.

When the display apparatus 1 is in a state before being folded, the first non-folding area NFA1 and the second non-folding area NFA2 may be arranged to be spaced apart from each other in a second direction (e.g., a +y direction or −y direction) crossing the first direction (e.g., the +x direction or −x direction). The first non-folding area NFA1 may be arranged to be spaced apart from the bending area BA, and the second non-folding area NFA2 may be arranged adjacent to the bending area BA.

The foldable area FA may be between the first non-folding area NFA1 and the second non-folding area NFA2. In detail, one side of the foldable area FA may be adjacent to the first non-folding area NFA1, and the other side of the foldable area FA may be adjacent to the second non-folding area NFA2. The foldable area FA may extend in a direction crossing a virtual straight line that connects the first non-folding area NFA1 and the second non-folding area NFA2 to each other. When the display apparatus 1 is in a state before being folded, the foldable area FA may extend in the first direction (e.g., the +x direction or −x direction).

A folding line FL may be provided in the foldable area FA in the first direction (e.g., the +x direction or −x direction) that is an extension direction of the foldable area FA. Accordingly, the display apparatus 1 may be folded in the foldable area FA. The foldable area FA and the folding line FL of the foldable area FA may overlap an area of the display apparatus 1 where an image is displayed, and when the display apparatus 1 is folded, a portion where an image is displayed may be folded. That is, the display apparatus 1 may display an image not only in the non-folding area but al in the folding area.

For convenience of description, FIG. 1 shows that the first non-folding area NFA1 and the second non-folding area NFA2 have the same or similar areas, and the display apparatus 1 includes one foldable area FA, but one or more embodiments are not limited thereto. For another example, the first non-folding area NFA1 and the second non-folding area NFA2 may have different areas. Also, the display apparatus 1 may include a plurality of foldable areas FA. In this case, a plurality of non-folding areas may be arranged to be spaced apart from each other, and each of the plurality of foldable areas FA may be between the non-folding areas. Each foldable area FA may be folded based on the folding line FL, and a plurality of folding lines FL may be provided.

In addition, FIG. 1 shows that the folding line FL passes through the center of the foldable area FA, and the foldable area FA is linearly symmetrical with respect to the folding line FL, but one or more embodiments are not limited thereto. For another example, the folding line FL may also be asymmetrically provided in the foldable area FA.

The display apparatus 1 may be folded such that the first surface S1 of the first non-folding area NFA1 and the first surface S1 of the second non-folding area NFA2 face each other based on the folding line FL. In other words, as the foldable area FA of the display apparatus 1 is bent, the first surface S1 of the first non-folding area NFA1 and the first surface S1 of the second non-folding area NFA2 may be arranged to face each other. Even when the display apparatus 1 is folded, the foldable area FA may extend in the direction crossing the virtual straight line that connects the first non-folding area NFA1 and the second non-folding area NFA2 to each other. In detail, when the display apparatus 1 is folded, the foldable area FA may extend in the first direction (e.g., the +x direction or −x direction) crossing the virtual straight line (e.g., a straight line parallel to the z-axis direction) that connects the first non-folding area NFA1 and the second non-folding area NFA2 to each other.

Moreover, the foldable area FA may be bent and then unfolded again. Accordingly, the display apparatus 1 may be unfolded. As used herein, “unfolding” may refer to a case where the display apparatus 1 is folded and then unfolded. That is, the display apparatus 1 may be a foldable display apparatus.

In addition, the term “folding” used herein means that the shape is not fixed but is transformed from the original shape into another shape, and may include a case where the display apparatus 1 is folded, curved, or bent along one or more specific lines, that is, the folding line FL. Accordingly, when the display apparatus 1 is folded, the first surface S1 of the first non-folding area NFA1 and the first surface S1 of the second non-folding area NFA2 are arranged parallel to each other and thus may face each other, and the first surface S1 of the first non-folding area NFA1 and the first surface S1 of the second non-folding area NFA2 may be formed at a certain angle (e.g., an acute angle, right angle, or obtuse angle) with the foldable area FA therebetween.

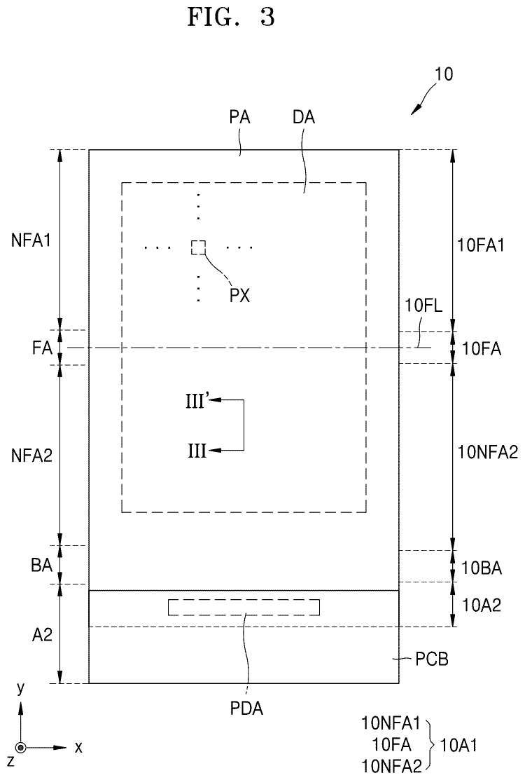

FIG. 3 is a schematic plan view of a display panel 10 included in the display apparatus 1, according to an embodiment. In detail, FIG. 3 is a schematic plan view showing a state in which the display panel 10 included in the display apparatus 1 is not bent, according to an embodiment. In FIG. 3, for convenience of description, a printed circuit board PCB included in the display apparatus 1 according to an embodiment is also shown.

The display panel 10 may display an image. To this end, the display panel 10 may include a plurality of display elements, and the plurality of display elements may emit light. Accordingly, the display panel 10 may display an image through light emitted from the plurality of display elements. In an embodiment, a display element may include an organic light-emitting diode including an organic emission layer. Alternatively, the display element may include a light-emitting diode (“LED”). A size of the LED may be in micro-scale or nano-scale. In an embodiment, for example, the LED may include a micro LED. Alternatively, the LED may include a nanorod LED. The nanorod LED may include gallium nitride (GaN). In an embodiment, a color conversion layer may be arranged over the nanorod LED. The color conversion layer may include quantum dots. Alternatively, the display element may include a quantum dot LED including a quantum dot emission layer. Alternatively, the display element may include an inorganic LED including an inorganic semiconductor. A detailed description of elements included in the display panel 10 will be provided below.

As described above, the display apparatus 1 may include the first area A1, the second area A2, and the bending area BA, and the first area A1 may include the first non-folding area NFA1, the second non-folding area NFA2, and the foldable area FA. Because the display apparatus 1 includes the display panel 10, areas included in the display panel 10 may correspond to areas of the display apparatus 1.

As shown in FIG. 3, the display panel 10 may include a first panel area 10A1, a second panel area 10A2, and a panel bending area 10BA between the first panel area 10A1 and the second panel area 10A2. The first panel area 10A1 may correspond to the first area A1, and the panel bending area 10BA may correspond to the bending area BA. The second panel area 10A2 and the printed circuit board PCB may correspond to the second area A2. Therefore, a repeated description regarding this will be omitted.

In detail, the first panel area 10A1 may include a first panel non-folding area 10NFA1, a second panel non-folding area 10NFA2, and a panel foldable area 10FA. The first panel non-folding area 10NFA1 may correspond to the first non-folding area NFA1, and the second panel non-folding area 10NFA2 may correspond to the second non-folding area NFA2. The panel foldable area 10FA may correspond to the foldable area FA, and a panel folding line 10FL corresponding to the folding line FL may be provided in the panel foldable area 10FA.

The panel bending area 10BA may be bent based on a panel bending axis (not shown) corresponding to the bending axis BAX. The second panel area 10A2 may overlap at least a portion of the printed circuit board PCB. That is, at least a portion of the printed circuit board PCB may be disposed on the second panel area 10A2. Because the display panel 10 is bent in the panel bending area 10BA, when seen in the z-axis direction, at least a portion of the second panel area 10A2 and the printed circuit board PCB may overlap the first panel area 10A1.

As shown in FIG. 3, the display panel 10 may include a display area DA in which a plurality of pixels PX are arranged, and a peripheral area PA located outside the display area DA. Each pixel PX of the display panel 10 is an area that may emit light of a certain color, and the display panel 10 may provide an image by using light emitted from the pixels PX. In an embodiment, for example, each pixel PX may emit red, green, or blue light.

The display area DA is an area where an image is provided, and may have a polygonal shape including a quadrangular shape, as shown in FIG. 3. In an embodiment, for example, the display area DA may have a rectangular shape in which a horizontal length is shorter than a vertical length, a rectangular shape in which a horizontal length is longer than a vertical length, or a square shape. Alternatively, the display area DA may have various shapes such as an elliptical or circular shape.

The peripheral area PA is a non-display area that does not provide an image, and may surround the entirety of the display area DA. In detail, the pixels PX may not be arranged in the peripheral area PA, and a driver, etc. for providing electrical signals or power to the pixels PX may be arranged in the peripheral area PA. In addition, as shown in FIG. 3, the peripheral area PA may include a pad area PDA, and pads (not shown) may be arranged in the pad area PDA.

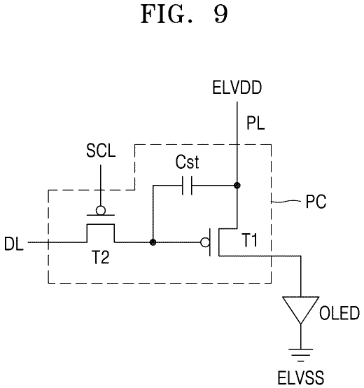

The display area DA may be arranged in the first panel area 10A1. A portion of the peripheral area PA may be arranged in the first panel area 10A1, another portion of the peripheral area PA may be arranged in the panel bending area 10BA, and another portion of the peripheral area PA may be arranged in the second panel area 10A2. In detail, the pad area PDA of the peripheral area PA may be arranged in the second panel area 10A2. In the pad area PDA, a plurality of pads may be arranged to be spaced apart from each other, and the pads may be electrically connected to a plurality of connection lines arranged in the peripheral area PA, respectively. The connection lines may electrically connect signal lines arranged in the display area DA, for example, data lines DL (see FIG. 9) (or scan lines SCL (see FIG. 9)), and the pads to each other. At least a portion of the printed circuit board PCB may be disposed on the second panel area 10A2, and as the pads of the pad area PDA are electrically connected to bumps of the printed circuit board PCB, the display panel 10 may be electrically connected to the printed circuit board PCB.

The printed circuit board PCB may include a flexible printed circuit board (“FPCB”) that is bendable, a rigid printed circuit board (“PCB”) that is hard and thus is not easily bendable, or a composite PCB including both a rigid PCB or an FPCB. In an embodiment, a power supplier for supplying driving voltages to drive the pixels PX of the display panel 10 and a scan driver may be additionally arranged over the printed circuit board PCB. In another embodiment, a driving chip including driving elements for driving the pixels PX of the display panel 10, such as a data driving circuit, may be mounted on the second panel area 10A2, and various types of driving elements to drive the driving chip may be mounted on the printed circuit board PCB.

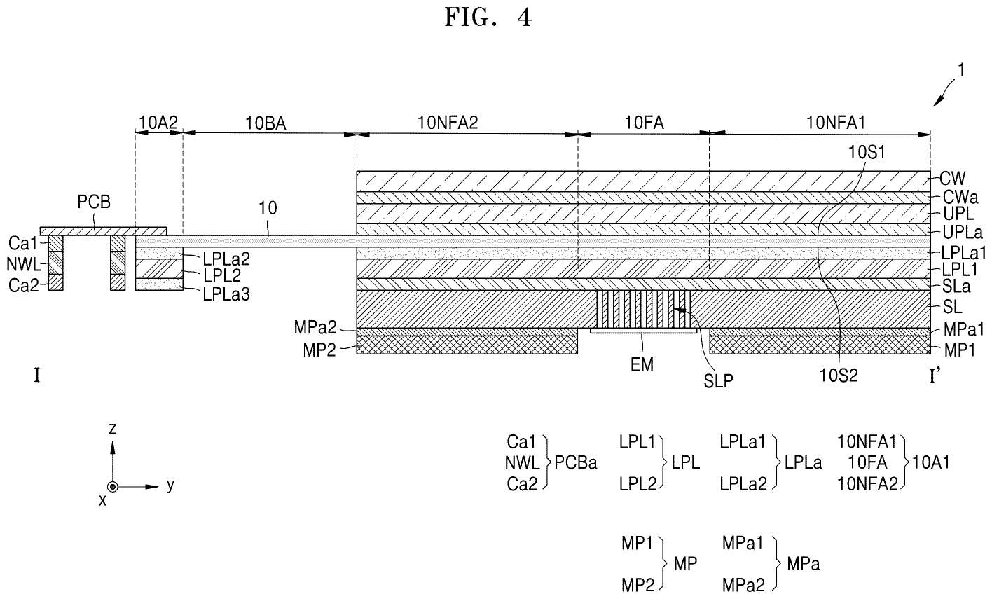

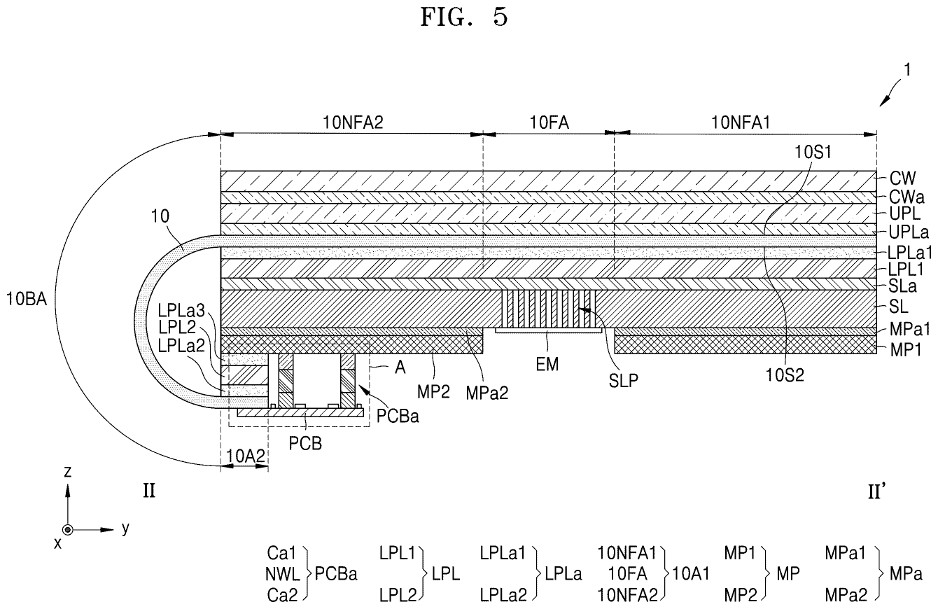

FIG. 4 is a schematic cross-sectional view of the display apparatus 1 in an unbent state, according to an embodiment, and FIG. 5 is a schematic cross-sectional view of the display apparatus 1 according to an embodiment. In detail, FIG. 4 is a schematic cross-sectional view showing a cross-section of the display apparatus 1 taken along line I-l′ of FIG. 1, and FIG. 5 is a schematic cross-sectional view showing a cross-section of the display apparatus 1 taken along line II-II′ of FIG. 2.

Referring to FIGS. 4 and 5, the display apparatus 1 may include the display panel 10, a cover window CW, an upper protective layer UPL, a lower protective layer LPL, a support layer SL, a metal plate MP, and the printed circuit board PCB. The display apparatus 1 may further include a cover window adhesive layer CWa, an upper protective layer adhesive layer UPLa, a lower protective layer adhesive layer LPLa, a support layer adhesive layer SLa, a metal plate adhesive layer MPa, and a printed circuit board adhesive layer PCBa.

The display panel 10 may include a first panel surface 10S1 and a second panel surface 10S2. The first panel surface 10S1 may correspond to the first surface S1 of the display apparatus 1, and the second panel surface 10S2 may correspond to the second surface S2 of the display apparatus 1. That is, the first panel surface 10S1 of the display panel 10 may face the same direction (e.g., a +z direction) as the first surface S1 of the display apparatus 1, and the second panel surface 10S2 of the display panel 10 may face the same direction (e.g., the −z direction) as the second surface S2 of the display apparatus 1. In other words, the display panel 10 may include the first panel surface 10S1 and the second panel surface 10S2 that is opposite to the first panel surface 10S1.

The display panel 10 may display an image on the first panel surface 10S1. That is, the first panel surface 10S1 of the display panel 10 may include a display surface. In detail, the first panel surface 10S1 of the first panel area 10A1 of the display panel 10 may include a display surface. As the display panel 10 is bent in the panel bending area 10BA, the second panel surface 10S2 of the first panel area 10A1 and the second panel surface 10S2 of the second panel area 10A2 may be arranged to face each other.

When the display panel 10 is in a state before being folded, the first panel non-folding area 10NFA1 and the second panel non-folding area 10NFA2 may be arranged to be spaced apart from each other in the second direction (e.g., the +y direction or −y direction) crossing the first direction (e.g., the +x direction or −x direction). The first panel non-folding area 10NFA1 may be arranged to be spaced apart from the panel bending area 10BA, and the second panel non-folding area 10NFA2 may be arranged adjacent to the panel bending area 10BA. The panel foldable area 10FA may be between the first panel non-folding area 10NFA1 and the second panel non-folding area 10NFA2 and may extend in the first direction (e.g., the +x direction or −x direction) crossing a virtual straight line that connects the first panel non-folding area 10NFA1 and the second panel non-folding area 10NFA2 to each other.

The panel folding line 10FL may be provided in the panel foldable area 10FA in the first direction (e.g., the +x direction or −x direction) that is the extension direction of the panel foldable area 10FA. Accordingly, the display panel 10 may be folded in the panel foldable area 10FA. The display panel 10 may be folded such that the first panel surface 10S1 of the first panel non-folding area 10NFA1 and the first panel surface 10S1 of the second panel non-folding area 10NFA2 face each other based on the panel folding line 10FL. In other words, as the panel foldable area 10FA of the display panel 10 is bent, the first panel surface 10S1 of the first panel non-folding area 10NFA1 and the first panel surface 10S1 of the second panel non-folding area 10NFA2 may be arranged to face each other.

The cover window CW may be arranged over the display panel 10. In detail, the cover window CW may be arranged over the first panel area 10A1 of the display panel 10. That is, the cover window CW may be arranged to cover the first panel surface 10S1 of the first panel area 10A1 of the display panel 10. The cover window CW may protect the first panel surface 10S1 of the first panel area 10A1 of the display panel 10.

The cover window CW may have a high transmittance to transmit light emitted from the display panel 10 and may have a small thickness to significantly reduce the weight of the display apparatus 1. Also, the cover window CW may have high strength and high hardness to protect the display panel 10 from external impact. The cover window CW may include a flexible window. The cover window CW may protect the display panel 10 by being easily bent according to external force without cracking or the like. The cover window CW may include glass or plastic. In an embodiment, the cover window CW may include ultra-thin tempered glass (“UTG”) of which hardness has been strengthened using methods such as chemical strengthening or thermal strengthening. In another embodiment, the cover window CW may include polymer resin.

The upper protective layer UPL may be between the display panel 10 and the cover window CW. The upper protective layer UPL may protect the display panel 10 and absorb external impact applied to an upper surface (in the +z direction) of the display panel 10. The upper protective layer UPL may include a plastic film including polymer resin. In an embodiment, for example, the upper protective layer UPL may include at least one of polymer resins such as polyethylene terephthalate (“PET”), polybutylene terephthalate (“PBT”), polycarbonate (“PC”), polyethylene naphthalate (“PEN”), polystyrene (“PS”), polymethylmethacrylate (“PMMA”), polyvinyl chloride (“PVC”), polyethersulfone (“PES”), polypropylene (“PP”), or polyamide (“PA”).

The lower protective layer LPL may be arranged over the second panel surface 10S2 of the display panel 10. In detail, the lower protective layer LPL may include a first lower protective layer LPL1 and a second lower protective layer LPL2. The first lower protective layer LPL1 may be arranged over the second panel surface 10S2 of the first panel area 10A1 of the display panel 10, and the second lower protective layer LPL2 may be arranged over the second panel surface 10S2 of the second panel area 10A2 of the display panel 10. In other words, as the display panel 10 is bent in the panel bending area 10BA, the second panel surface 10S2 of the first panel area 10A1 and the second panel surface 10S2 of the second panel area 10A2 are arranged to face each other, and accordingly, the first lower protective layer LPL1 may be arranged in the −z direction of the second panel surface 10S2 of the first panel area 10A1 of the display panel 10, and the second lower protective layer LPL2 may be arranged in the +z direction of the second panel surface 10S2 of the second panel area 10A2 of the display panel 10. The first lower protective layer LPL1 and the second lower protective layer LPL2 may be spaced apart from each other with the panel bending area 10BA therebetween. That is, because the lower protective layer LPL is not arranged over the second panel surface 10S2 of the panel bending area 10BA, the display panel 10 may be easily bent.

The lower protective layer LPL may protect the display panel 10 from the outside. In an embodiment, for example, the lower protective layer LPL may absorb physical impact from the outside, and the lower protective layer LPL may block foreign substances or moisture from penetrating the display panel 10. In an embodiment, the lower protective layer LPL may include an organic insulating material such as PET, polyimide (“PI”), or urethane acrylate.

In some embodiments, the lower protective layer LPL may further include a material that blocks ultraviolet rays (“UV”). In an embodiment, for example, the lower protective layer LPL may include a base resin, a UV absorber, and inorganic particles. The UV absorber and the inorganic particles may be provided by being dispersed in the base resin. The base resin may include an acrylate-based resin, for example, urethane acrylate. However, one or more embodiments are not limited thereto, and a base resin that is optically transparent and capable of dispersing the UV absorber and the inorganic particles may be used in the lower protective layer LPL without limitation. In an embodiment, for example, the UV absorber may include at least one of a benzotriazole-based compound, a benzophenone-based compound, a salicylic acid-based compound, a salicylate-based compound, a cyanoacrylate-based compound, a cinnamate-based compound, an oxanilide-based compound, a polystyrene-based compound, an azomethine-based compound, and a triazine-based compound.

The support layer SL may be arranged under the lower protective layer LPL. The support layer SL may be arranged under the lower protective layer LPL and support the display panel 10. Accordingly, the degree to which the center of the display panel 10 sags in the −z direction due to its weight is reduced, and thus, the display panel 10 may not be easily damaged even when external impact is applied.

The support layer SL may include a folding pattern SLP. When the display apparatus 1 is folded, the shape of the folding pattern SLP may be variable or the length of the folding pattern SLP may be variable. Accordingly, the support layer SL may be more easily folded. In an embodiment, for example, the folding pattern SLP may be an opening provided in the support layer SL. In another embodiment, the folding pattern SLP may have an uneven shape. In another embodiment, the folding pattern SLP may include links rotatably connected to each other.

The support layer SL may include at least one of a metal, glass, and plastic. In an embodiment, the support layer SL may include polyurethane. In another embodiment, the support layer SL may include carbon fiber-reinforced plastic (“CFRP”). In an embodiment, the folding pattern SLP may include the same material as or a different material from the support layer SL.

The metal plate MP may be arranged under the support layer SL. In detail, the metal plate MP may include a first metal plate MP1 and a second metal plate MP2, and the first metal plate MP1 and the second metal plate MP2 may be arranged to be separated from each other around the panel foldable area 10FA. In other words, the first metal plate MP1 and the second metal plate MP2 may be arranged to be separated from each other with the panel foldable area 10FA therebetween. That is, the first metal plate MP1 may be arranged under the first panel non-folding area 10NFA1, and the second metal plate MP2 may be arranged under the second panel non-folding area 10NFA2. The metal plate MP may absorb impact from the outside and protect the display panel 10.

The metal plate MP may be a plate including a metal material. That is, the metal plate MP may include a metal material. The metal plate MP may include a metal or an alloy between at least two metals. In an embodiment, for example, the metal plate MP may include aluminum (AI), copper (Cu), iron (Fe), or chromium (Cr). However, one or more embodiments are not limited thereto.

In addition, an elastic member EM may be arranged under a portion of the support layer SL, which is arranged under the panel foldable area 10FA. In detail, the elastic member EM may cover the folding pattern SLP. The elastic member EM may improve the durability of the support layer SL. The elastic member EM may include thermoplastic polyurethane (“TPU”).

In this case, each of a plurality of adhesive layers is between elements of the display apparatus 1, and accordingly, one element of the display apparatus 1 may be attached to another element of the display apparatus 1. In detail, the upper protective layer adhesive layer UPLa may be between the display panel 10 and the upper protective layer UPL. The upper protective layer adhesive layer UPLa may attach the upper protective layer UPL to the display panel 10. The cover window adhesive layer CWa may be between the upper protective layer UPL and the cover window CW. The cover window adhesive layer CWa may attach the cover window CW to the upper protective layer UPL.

Similarly, the lower protective layer adhesive layer LPLa may be between the display panel 10 and the lower protective layer LPL. The lower protective layer adhesive layer LPLa may include a first lower protective layer adhesive layer PLa1 and a second lower protective layer adhesive layer PLa2. In detail, the first lower protective layer adhesive layer PLa1 may be between the display panel 10 and the first lower protective layer LPL1, and the second lower protective layer adhesive layer PLa2 may be between the display panel 10 and the second lower protective layer LPL2. The lower protective layer LPL may be attached in the form of a film to the second panel surface 10S2 of the display panel 10 via the lower protective layer adhesive layer LPLa.

Similarly, the support layer adhesive layer SLa may be between the lower protective layer LPL and the support layer SL. In detail, the support layer adhesive layer SLa may be between the first lower protective layer LPL1 and the support layer SL. The support layer adhesive layer SLa may attach the support layer SL to the first lower protective layer LPL1. The metal plate adhesive layer MPa may be between the support layer SL and the metal plate MP. The metal plate adhesive layer MPa may include a first metal plate adhesive layer MPa1 and a second metal plate adhesive layer MPa2. In detail, the first metal plate adhesive layer MPa1 may be between the support layer SL and the first metal plate MP1, and the second metal plate adhesive layer MPa2 may be between the support layer SL and the second metal plate MP2. The metal plate adhesive layer MPa may attach the metal plate MP to the support layer SL.

The cover window adhesive layer CWa, the upper protective layer adhesive layer UPLa, the lower protective layer adhesive layer LPLa, the support layer adhesive layer SLa, and the metal plate adhesive layer MPa may include an adhesive member such as an optical clear adhesive (“OCA”) or a pressure sensitive adhesive (“PSA”). However, one or more embodiments are not limited thereto.

As shown in FIG. 5, in a state in which the panel bending area 10BA of the display panel 10 is bent, the second panel surface 10S2 of the first panel area 10A1 and the second panel surface 10S2 of the second panel area 10A2 may be arranged to face each other. Accordingly, in a state in which the panel bending area 10BA of the display panel 10 is bent, the second lower protective layer LPL2 of the second panel area 10A2 may be arranged under the first panel area 10A1 and the first lower protective layer LPL1, along with the second panel area 10A2. In an embodiment, the display panel 10 may further include a third lower protective layer adhesive layer LPLa3. The second lower protective layer LPL2 may be attached to a lower surface (in the −z direction) of the metal plate MP via the third lower protective layer adhesive layer LPLa3. The third lower protective layer adhesive layer LPLa3 may include an adhesive member such as an OCA or a PSA. In another embodiment, the third lower protective layer adhesive layer LPLa3 may be omitted.

In addition, the printed circuit board PCB at least partially overlapping the second panel area 10A2 may also be arranged under the first panel area 10A1 and the first lower protective layer LPL1 in a state in which the panel bending area 10BA of the display panel 10 is bent. In a state in which the panel bending area 10BA of the display panel 10 is bent, the printed circuit board adhesive layer PCBa may be between the printed circuit board PCB and the metal plate MP.

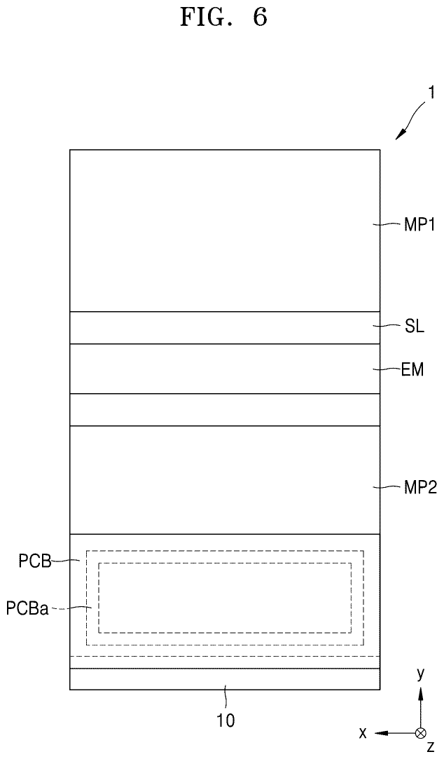

FIG. 6 is a schematic rear view of the display apparatus 1 according to an embodiment. In detail, FIG. 6 is a rear view of the display apparatus 1 when the display apparatus 1 of FIG. 5 is seen in the +z direction. For convenience of description, the printed circuit board adhesive layer PCBa is also shown in FIG. 6.

As shown in FIG. 6, in a plan view, the printed circuit board adhesive layer PCBa may be arranged along the outer portion of the printed circuit board PCB to surround at least a portion of the printed circuit board PCB. In an embodiment, for example, the printed circuit board adhesive layer PCBa may be continuously arranged along the circumference of the printed circuit board PCB to form a closed loop.

In an embodiment, the printed circuit board adhesive layer PCBa may be a double-sided adhesive tape, specifically, a conductive double-sided adhesive tape. Accordingly, the printed circuit board PCB may be attached to the lower surface (in the −z direction) of the metal plate MP by the printed circuit board adhesive layer PCBa. In detail, the printed circuit board PCB may be attached to a lower surface (in the −z direction) of the second metal plate MP2 by the printed circuit board adhesive layer PCBa. The printed circuit board adhesive layer PCBa may compensate for a step formed by the second lower protective layer LPL2 on the lower surface (in the −z direction) of the second metal plate MP2. In this case, the printed circuit board adhesive layer PCBa may have a thickness sufficient to compensate for the step.

The printed circuit board adhesive layer PCBa may include a conductive nonwoven layer NWL, and a first conductive adhesive layer Ca1 and a second conductive adhesive layer Ca2, which are arranged on opposite sides of the conductive nonwoven layer NWL, respectively, with the conductive nonwoven layer NWL therebetween. That is, the printed circuit board adhesive layer PCBa may include the first conductive adhesive layer Ca1, the second conductive adhesive layer Ca2, and the conductive nonwoven layer NWL between the first conductive adhesive layer Ca1 and the second conductive adhesive layer Ca2.

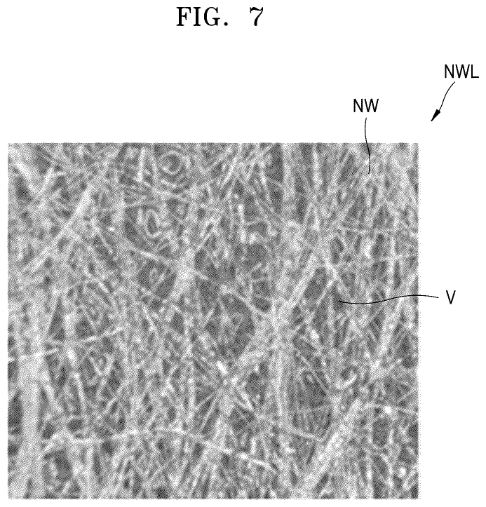

The conductive nonwoven layer NWL may include a nonwoven fabric plated with a metal material such as Cu or nickel (Ni). That is, the conductive nonwoven layer NWL may have a structure in which a nonwoven fabric is plated with a metal material such as Cu or Ni. As shown in FIG. 7, which is micrograph of the conductive nonwoven layer NWL included in the display apparatus 1 according to an embodiment, the conductive nonwoven layer NWL may include a nonwoven fabric NW plated with a metal material such as Cu or Ni, and the conductive nonwoven layer NWL may have voids V in the nonwoven fabric NW. The specific gravity of voids V of the conductive nonwoven layer NWL may vary according to a process performed when the conductive nonwoven layer NWL is formed.

In an embodiment, the conductive nonwoven layer NWL may be a conductive nonwoven layer on which a cire process has not been performed. With respect to the specific gravity of the voids V of the conductive nonwoven layer NWL, the specific gravity of the voids V of the conductive nonwoven layer NWL on which the cire process has not been performed may be higher than the specific gravity of the voids V of the conductive nonwoven layer NWL on which the cire process has been performed. Because the specific gravity of the voids V of the conductive nonwoven layer NWL is high, even when a rear surface of the printed circuit board PCB in contact with the printed circuit board adhesive layer PCBa has an uneven surface structure, the uneven surface structure may be alleviated by the voids V. That is, a surface structure of the printed circuit board PCB is not transferred to the metal plate MP due to the voids V, and thus, deformation of the metal plate MP may be prevented. Accordingly, a phenomenon in which deformation of the metal plate MP is seen as a stain on the display apparatus 1 may be prevented or reduced.

The first conductive adhesive layer Ca1 may be between the conductive nonwoven layer NWL and the printed circuit board PCB. That is, the first conductive adhesive layer Ca1 may be in direct contact with one surface of the printed circuit board PCB. The second conductive adhesive layer Ca2 may be between the conductive nonwoven layer NWL and the metal plate MP. In detail, the second conductive adhesive layer Ca2 may be between the conductive nonwoven layer NWL and the second metal plate MP2. That is, the second conductive adhesive layer Ca2 may be in direct contact with one surface of the second metal plate MP2. The first conductive adhesive layer Ca1 and the second conductive adhesive layer Ca2 may include a conductive adhesive material. In an embodiment, the first conductive adhesive layer Ca1 and the second conductive adhesive layer Ca2 may be films formed by dispersing metal particles including a metal, for example, gold (Au), silver (Ag), platinum (Pt), or Ni, in a synthetic resin. The synthetic resin may include a material such as epoxy, silicone, PI, or polyurethane. However, one or more embodiments are not limited thereto.

The first conductive adhesive layer Ca1 may be electrically connected to a ground wire (not shown) of the printed circuit board PCB. Accordingly, the printed circuit board adhesive layer PCBa may be configured to receive a ground voltage from the printed circuit board PCB and transfer the ground voltage to the metal plate MP. Accordingly, in the display apparatus 1, an electrostatic path formed by electrically connecting the ground wire, the printed circuit board adhesive layer PCBa, and the metal plate MP to each other may be provided.

In general, static electricity generated during a manufacturing process or in a completed state of a display apparatus may flow into the display apparatus and cause malfunction or damage to the display apparatus. In the case of display apparatus 1 according to the present embodiment, the electrostatic path formed by electrically connecting the ground wire, the printed circuit board adhesive layer PCBa, and the metal plate MP to each other may be provided. Accordingly, even when static electricity flows into the display apparatus 1, for example, into the printed circuit board PCB, the static electricity may be discharged through the electrostatic path. Therefore, the display apparatus 1 may be effectively prevented from malfunctioning or being damaged by the static electricity.

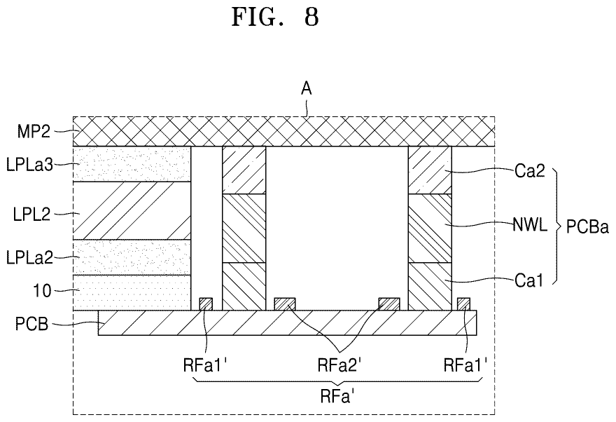

As shown in FIG. 8, which is a schematic enlarged cross-sectional view of an area A of the display apparatus 1 of FIG. 5, a residual adhesive layer RFa′ may be between the printed circuit board PCB and the second metal plate MP2 in a state in which the panel bending area 10BA of the display panel 10 is bent. The residual adhesive layer RFa′ may include a first residual adhesive layer RFa1′ and a second residual adhesive layer RFa2′. In detail, the residual adhesive layer RFa′ may be arranged on one surface of the printed circuit board PCB in contact with the printed circuit board adhesive layer PCBa. In other words, the residual adhesive layer RFa′ may be arranged on the rear surface of the printed circuit board PCB. In a plan view, the residual adhesive layer RFa′ may be arranged to be spaced apart from the printed circuit board adhesive layer PCBa. Also, in a plan view, the residual adhesive layer RFa′ may be arranged along the outside of the printed circuit board adhesive layer PCBa to surround at least a portion of the printed circuit board adhesive layer PCBa. A detailed description of the residual adhesive layer RFa′ will be provided below.

Moreover, though not shown, a bending protective layer may be arranged over the bending area BA. In detail, the bending protective layer may be arranged over the first panel surface 10S1 of the bending area BA. The bending protective layer may protect the bent display panel 10 from external impact and may support the display panel 10 to maintain a good shape when the display panel 10 is bent. Also, because the bending protective layer is provided, stress applied to the bending area BA of the display panel 10 may be significantly reduced. When a stacked structure including the display panel 10 is bent, compressive stress or tensile stress may be applied to portions of the stacked structure according to locations thereof. A neutral plane, which is a location where compressive stress and tensile stress are 0 (zero), may be present within the stacked structure. That is, when the stacked structure including the display panel 10 is bent, compressive stress may be applied to the inside of the neutral plane, while tensile stress may be applied to the outside of the neutral plane. As a distance from the neutral plane increases, greater compressive stress or tensile stress may be applied to a portion of the stacked structure. The bending protective layer may move the neutral plane within the stacked structure including the display panel 10. That is, by appropriately adjusting a thickness and/or modulus of the bending protective layer, stress applied to the bending area BA of the display panel 10 may be adjusted. Accordingly, there may be no stress applied to the display panel 10, and even when there is stress, the stress may be significantly reduced.

FIG. 9 is an equivalent circuit diagram of one pixel PX of the display panel 10 of FIG. 3. As shown in FIG. 9, one pixel PX may correspond to one display element, and the display element may be electrically connected to a pixel circuit PC. In FIG. 9, an organic light-emitting diode OLED is shown as a display element.

The pixel circuit PC may include a first transistor T1, a second transistor T2, and a storage capacitor Cst. The second transistor T2, which is a switching transistor, may be connected to a scan line SCL and a data line DL, may be turned on in response to a switching signal input from the scan line SCL, and may be configured to transmit, to the first transistor T1, a data signal input from the data line DL. One end of the storage capacitor Cst may be electrically connected to the second transistor T2, and the other end of the storage capacitor Cst may be electrically connected to a driving voltage line PL, and the storage capacitor Cst may store a voltage corresponding to a difference between a voltage received from the second transistor T2 and a driving power voltage ELVDD supplied to the driving voltage line PL.

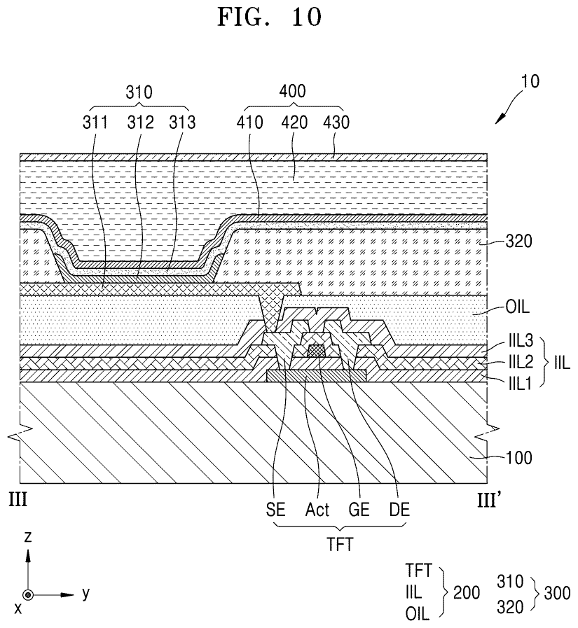

The first transistor T1, which is a driving transistor, may be connected to the driving voltage line PL and the storage capacitor Cst and may be configured to control a magnitude of a driving current flowing through the organic light-emitting diode OLED from the driving voltage line PL in response to a value of the voltage stored in the storage capacitor Cst. The organic light-emitting diode OLED may emit light with a certain brightness according to the driving current. An opposite electrode 313 (see FIG. 10) of the organic light-emitting diode OLED may receive an electrode power voltage ELVSS.

FIG. 9 illustrates that the pixel circuit PC includes two transistors and one storage capacitor, but one or more embodiments are not limited thereto. For another example, the number of transistors or the number of capacitors may be various changed according to the design of the pixel circuit PC.

FIG. 10 is a schematic cross-sectional view of the display panel 10 included in the display apparatus 1, according to an embodiment. In detail, FIG. 10 is a schematic cross-sectional view showing a cross-section of the display panel 10 taken along line III-III′ of FIG. 3.

As shown in FIG. 10, the display panel 10 may include a substrate 100, a pixel circuit layer 200, a display element layer 300, and an encapsulation layer 400. The substrate 100 may include glass, a metal, or polymer resin. The substrate 100 may be flexible or bendable. In this case, the substrate 100 may include, for example, polymer resin such as PES, polyacrylate, polyetherimide, PEN, PET, polyphenylene sulfide, polyarylate, PI, PC, or cellulose acetate propionate. Various modifications may be made to the substrate 100. In an embodiment, for example, the substrate 100 may have a multilayer structure including two layers including the above polymer resin and a barrier layer that includes an inorganic material (e.g., silicon oxide (SiO_{X}), silicon nitride (SiN_{X}), silicon oxynitride (SiO_{X}N_{Y}), or the like) and is between the two layers.

The pixel circuit layer 200 may be disposed on the substrate 100. The pixel circuit layer 200 may include a thin-film transistor TFT, an inorganic insulating layer IIL, and an organic insulating layer OIL. The thin-film transistor TFT may include a semiconductor layer Act, a gate electrode GE, a source electrode SE, and a drain electrode DE. The inorganic insulating layer IIL may include a gate insulating layer IIL1, a first interlayer-insulating layer IIL2, and a second interlayer-insulating layer IIL3. For convenience of illustration, only one thin-film transistor TFT is shown in FIG. 10, and the thin-film transistor TFT may correspond to the aforementioned first transistor T1.

The semiconductor layer Act may be disposed on the substrate 100. The semiconductor layer Act may include polysilicon. Alternatively, the semiconductor layer Act may include amorphous silicon, may include an oxide semiconductor, or may include an organic semiconductor or the like. In an embodiment, the semiconductor layer Act may include a channel region, and a source region and a drain region arranged on opposite sides of the channel region, respectively.

The gate insulating layer IIL1 may be disposed on the semiconductor layer Act and the substrate 100. The gate insulating layer IIL1 may include an inorganic insulating material such as SiO_{X}, SiNₓ, SiO_{X}N_{Y}, aluminum oxide (Al₂O₃), titanium oxide (TiO₂), tantalum oxide (Ta₂O₅), hafnium oxide (HfO₂), or zinc oxide (ZnOₓ). The ZnOₓ may include zinc oxide (ZnO) and/or zinc peroxide (ZnO₂).

The gate electrode GE may be disposed on the gate insulating layer IIL1. That is, because the gate insulating layer IIL1 is between the semiconductor layer Act and the gate electrode GE, insulation between the semiconductor layer Act and the gate electrode GE may be secured. The gate electrode GE may overlap the channel region of the semiconductor layer Act in a plan view. The gate electrode GE may include a low-resistance metal material. In an embodiment, the gate electrode GE may include a conductive material including molybdenum (Mo), Al, Cu, or titanium (Ti) and may have a single-layer or multilayer structure including the aforementioned conductive material.

The first interlayer-insulating layer IIL2 may be disposed on the gate electrode GE and the gate insulating layer IIL1. The first interlayer-insulating layer IIL2 may include an inorganic insulating material such as SiO_{X}, SiNₓ, SiO_{X}N_{Y}, Al₂O₃, TiO₂, Ta₂O₅, HfO₂, or ZnOₓ.

The source electrode SE and the drain electrode DE may be disposed on the first interlayer-insulating layer IIL2. The source electrode SE and the drain electrode DE may be connected to the semiconductor layer Act through contact holes defined in the gate insulating layer IIL1 and the first interlayer-insulating layer IIL2, respectively. At least one of the source electrode SE and the drain electrode DE may include a conductive material including Mo, Al, Cu, or Ti and may have a single-layer or multilayer structure including the aforementioned conductive material. In an embodiment, at least one of the source electrode SE and the drain electrode DE may have a multilayer structure of Ti/Al/Ti.

The second interlayer-insulating layer IIL3 may be disposed on the source electrode SE, the drain electrode DE, and the first interlayer-insulating layer IIL2. The second interlayer-insulating layer IIL3 may include an inorganic insulating material such as SiO_{X}, SiNₓ, SiO_{X}N_{Y}, Al₂O₃, TiO₂, Ta₂O₅, HfO₂, or ZnOₓ.

The organic insulating layer OIL may be disposed on the second interlayer-insulating layer IIL3. The organic insulating layer OIL may substantially planarize the top of the pixel circuit layer 200. The organic insulating layer OIL may include an organic material such as acryl, benzocyclobutene (“BCB”), or hexamethyldisiloxane (“HMDSO”). Although FIG. 10 shows that the organic insulating layer OIL includes a single layer, various modifications may be made. In an embodiment, for example, the organic insulating layer OIL may include a multilayer.

The display element layer 300 may be disposed on the pixel circuit layer 200. The display element layer 300 may include a display element 310 and a pixel-defining layer 320. The display element 310 may be electrically connected to the thin-film transistor TFT. The display element 310 may include an organic light-emitting diode including, for example, a pixel electrode 311, an opposite electrode 313, and an intermediate layer 312 that is provided therebetween and includes an emission layer. When the display element 310 is electrically connected to the thin-film transistor TFT, it may be understood that the pixel electrode 311 of the organic light-emitting diode is electrically connected to the thin-film transistor TFT.

The pixel electrode 311 may be electrically connected to the thin-film transistor TFT by being in contact with one of the source electrode SE and the drain electrode DE through a contact hole defined in the second interlayer-insulating layer IIL3 and the organic insulating layer OIL. The pixel electrode 311 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 311 may include a reflective layer including Ag, magnesium (Mg), Al, Pt, palladium (Pd), Au, Ni, neodymium (Nd), iridium (Ir), Cr, or any compound thereof. In another embodiment, the pixel electrode 311 may further include a layer over/under the reflective layer, the layer including ITO, IZO, ZnO, or In₂O₃.

The pixel-defining layer 320 may cover an edge of the pixel electrode 311. The pixel-defining layer 320 may define a pixel opening therein, and the pixel opening may overlap the pixel electrode 311 in a plan view. The pixel opening may define an emission area of light emitted from the display element 310. The pixel-defining layer 320 may include an organic insulating material and/or an inorganic insulating material. In some embodiments, the pixel-defining layer 320 may include a light blocking material.

The intermediate layer 312 may be disposed on the pixel electrode 311 and the pixel-defining layer 320. The intermediate layer 312 may include a low molecular weight or a polymer material. When the intermediate layer 312 includes a low molecular weight material, the intermediate layer 312 may have a single-layer or multilayer structure in which a hole injection layer (“HIL”), a hole transport layer (“HTL”), an emission layer (“EML”), an electron transport layer (“ETL”), and an electron injection layer (“EIL”) are stacked. The intermediate layer 312 may be formed using vacuum deposition. When the intermediate layer 312 includes a polymer material, the intermediate layer 312 may have a structure including an HTL and an EML. In this case, the HTL may include poly(3,4-ethylenedioxythiophene) (“PEDOT”), and the EML may include a polymer material such as a polyphenylene vinylene (“PPV”)-based material or a polyfluorene-based material. The intermediate layer 312 may be formed using screen printing, inkjet printing, or laser induced thermal image (“LITI”). The intermediate layer 312 is not necessarily limited thereto. The intermediate layer 312 may have various structures. Also, the intermediate layer 312 may include an integrated layer over a plurality of pixel electrodes 311, or may include layers patterned to correspond to the plurality of pixel electrodes 311, respectively.

The opposite electrode 313 may be disposed on the intermediate layer 312 and the pixel-defining layer 320. The opposite electrode 313 may be integrally formed as a single body across a plurality of organic light-emitting diodes and correspond to the plurality of pixel electrodes 311. The opposite electrode 313 may include a light-transmissive conductive layer such as ITO, In₂O₃, or IZO and may also include a semi-transmissive layer including a metal such as Al or Ag. In an embodiment, for example, the opposite electrode 313 may include a semi-transmissive layer including Mg or Ag.

Because each display element 310 may be easily damaged by external moisture, oxygen, or the like, the encapsulation layer 400 may cover and protect the display element 310. As shown in FIG. 10, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and include SiO_{X}, SiN_{X}, and/or SiO_{X}N_{Y}. Other layers such as a capping layer may be between the first inorganic encapsulation layer 410 and the opposite electrode 313. Because the first inorganic encapsulation layer 410 is formed along a structure thereunder, an upper surface of the first inorganic encapsulation layer 410 may not be flat as shown in FIG. 10. The organic encapsulation layer 420 may cover the first inorganic encapsulation layer 410. Unlike the first inorganic encapsulation layer 410, an upper surface of the organic encapsulation layer 420 may be substantially flat. The organic encapsulation layer 420 may include one or more materials selected from among PET, PEN, PC, PI, polyethylene sulfonate, polyoxymethylene, polyarylate, and HMDSO. The second inorganic encapsulation layer 430 may cover the organic encapsulation layer 420 and include SiO_{X}, SiN_{X}, and/or SiO_{X}N_{Y}.

Accordingly, because the encapsulation layer 400 includes the first inorganic encapsulation layer 410, the organic encapsulation layer 420, and the second inorganic encapsulation layer 430, even when cracks occur in the encapsulation layer 400, due to this multilayer structure, the cracks may not be connected between the first inorganic encapsulation layer 410 and the organic encapsulation layer 420 or between the organic encapsulation layer 420 and the second inorganic encapsulation layer 430. Thus, the formation of a path through which external moisture, oxygen, or the like penetrates into the display panel 10 may be prevented or significantly reduced.

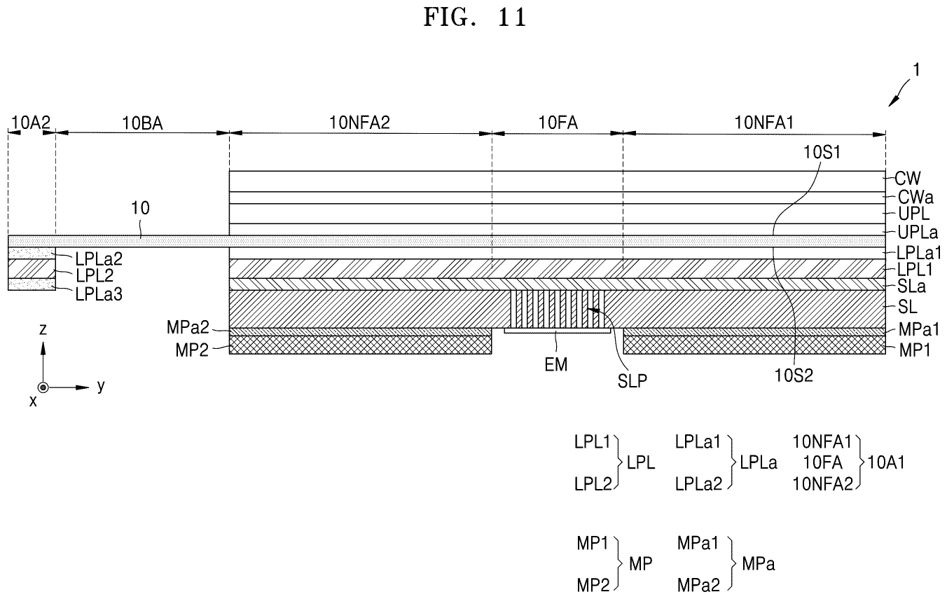

FIGS. 11 to 16 are diagrams for describing a method of manufacturing a display apparatus, according to an embodiment. In FIGS. 11, 14, 15, and 16, for convenience of description, the method of manufacturing the display apparatus will be described based on the cross-section of the display apparatus 1 taken along line II-II′ of FIG. 2. Hereinafter, in descriptions of the method of manufacturing the display apparatus according to an embodiment with reference to FIGS. 11 to 16, the same reference numeral as those in FIGS. 1 to 10 denote the same members as those in FIGS. 1 to 10, and repeated descriptions thereof will be omitted.

First, as shown in FIG. 11, the display panel 10 may be provided. In providing of a display panel, the display panel 10 may be flat without a portion of the display panel 10 being bent. In an embodiment, for example, the display panel 10 may include the first panel area 10A1, the second panel area 10A2, and the panel bending area 10BA. The panel bending area 10BA may be between the first panel area 10A1 and the second panel area 10A2, and the panel bending area 10BA of the display panel 10 may not be bent.

In the providing of the display panel, the display panel 10 may have the metal plate MP attached under the first panel area 10A1. In detail, the lower protective layer LPL may be arranged under the display panel 10, the support layer SL may be arranged under the lower protective layer LPL, and the metal plate MP may be arranged under the support layer SL. That is, the first lower protective layer LPL1 to which a first lower protective layer adhesive layer LPLa1 is attached may be attached to the second panel surface 10S2 of the first panel area 10A1 of the display panel 10, and the second lower protective layer LPL2 to which a second lower protective layer adhesive layer LPLa2 is attached may be attached to the second panel surface 10S2 of the second panel area 10A2 of the display panel 10. The support layer SL to which the support layer adhesive layer SLa is attached may be attached to the first lower protective layer LPL1, and the elastic member EM may be attached to the support layer SL to cover the folding pattern SLP of the support layer SL overlapping the panel foldable area 10FA. The first metal plate MP1 to which the first metal plate adhesive layer MPa1 is attached may be attached to a portion of the support layer SL overlapping the first panel non-folding area 10NFA1 of the display panel 10, and the second metal plate MP2 to which the second metal plate adhesive layer MPa2 is attached may be attached to a portion of the support layer SL overlapping the second panel non-folding area 10NFA2 of the display panel 10. That is, the metal plate MP may be attached to the underside of the first panel area 10A1.

Moreover, the upper protective layer UPL may be arranged over the display panel 10, and the cover window CW may be arranged over the upper protective layer UPL. The upper protective layer UPL to which the upper protective layer adhesive layer UPLa is attached may be attached to the first panel surface 10S1 of the first panel area 10A1 of the display panel 10, and the cover window CW to which the cover window adhesive layer CWa is attached may be attached to the upper protective layer UPL.

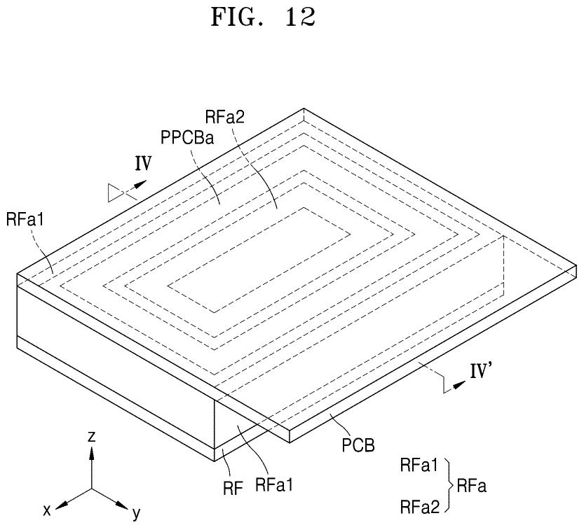

Next, as shown in FIG. 12, the printed circuit board PCB may be provided. A preliminary printed circuit board adhesive layer PPCBa may be attached to one surface of the printed circuit board PCB. In detail, the preliminary printed circuit board adhesive layer PPCBa may be attached to a rear surface of the printed circuit board PCB. The rear surface of the printed circuit board PCB may be one surface of the printed circuit board PCB to be in contact with the second panel area 10A2 when the printed circuit board PCB is bonded to the second panel area 10A2 of the display panel 10. That is, the rear surface of the printed circuit board PCB may be one surface where bumps of the printed circuit board PCB to be electrically connected to pads of the second panel area 10A2 are arranged. In other words, the rear surface of the printed circuit board PCB may be one surface of the printed circuit board PCB toward the display panel 10.

In a plan view, the preliminary printed circuit board adhesive layer PPCBa may be arranged along the outer portion of the printed circuit board PCB to surround at least a portion of the printed circuit board PCB. In an embodiment, for example, the preliminary printed circuit board adhesive layer PPCBa may be continuously arranged along the periphery of the printed circuit board PCB to form a closed loop.

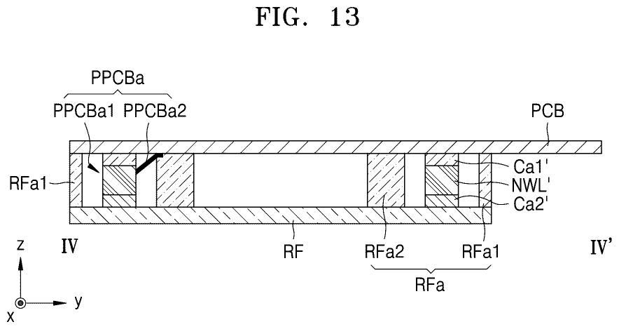

As shown in FIG. 13, which is a schematic cross-sectional view of the printed circuit board PCB, the preliminary printed circuit board adhesive layer PPCBa, a release film RF, and a release film adhesive layer RFa taken along line IV-IV′ of FIG. 12, the preliminary printed circuit board adhesive layer PPCBa may include a first portion PPCBa1 and a second portion PPCBa2. The first portion PPCBa1 may be a portion of the preliminary printed circuit board adhesive layer PPCBa corresponding to the printed circuit board adhesive layer PCBa described above with reference to FIGS. 1 and 10, and the second portion PPCBa2 may be a portion of the preliminary printed circuit board adhesive layer PPCBa other than the first portion PPCBa1. That is, in a plan view, the first portion PPCBa1 may be arranged along the outer portion of the printed circuit board PCB to surround at least a portion of the printed circuit board PCB. In an embodiment, for example, the first portion PPCBa1 may be continuously arranged along the periphery of the printed circuit board PCB to form a closed loop.

The first portion PPCBa1 may include a conductive nonwoven layer NWL′, and a first conductive adhesive layer Ca1′ and a second conductive adhesive layer Ca2′, which arranged on opposite sides of the conductive nonwoven layer NWL′, respectively, with the conductive nonwoven layer NWL′ therebetween. That is, the first portion PPCBa1 may include the first conductive adhesive layer Ca1′, the second conductive adhesive layer Ca2′, and the conductive nonwoven layer NWL′ between the first conductive adhesive layer Ca1′ and the second conductive adhesive layer Ca2′. The conductive nonwoven layer NWL′, the first conductive adhesive layer Ca1′, and the second conductive adhesive layer Ca2′ of the first portion PPCBa1 may correspond to the conductive nonwoven layer NWL, the first conductive adhesive layer Ca1, and the second conductive adhesive layer Ca2 of the printed circuit board adhesive layer PCBa, respectively.

In detail, the conductive nonwoven layer NWL′ may include a nonwoven fabric plated with a metal material such as Cu or Ni. That is, the conductive nonwoven layer NWL′ may have a structure in which a nonwoven fabric is plated with a metal material such as Cu or Ni. The conductive nonwoven layer NWL′ may include a nonwoven fabric plated with a metal material such as Cu or Ni, and the conductive nonwoven layer NWL′ may have voids in a conductive nonwoven fabric.

The first conductive adhesive layer Ca1′ may be between the conductive nonwoven layer NWL′ and the printed circuit board PCB. That is, the first conductive adhesive layer Ca1′ may be in direct contact with one surface of the printed circuit board PCB, and the first conductive adhesive layer Ca1′ may be attached to the printed circuit board PCB. The second conductive adhesive layer Ca2′ may be arranged opposite to the first conductive adhesive layer Ca1′ with the conductive nonwoven layer NWL′ therebetween. That is, the second conductive adhesive layer Ca2′ may be in direct contact with one surface of the release film RF.

The first conductive adhesive layer Ca1′ and the second conductive adhesive layer Ca2′ may include a conductive adhesive material. In an embodiment, the first conductive adhesive layer Ca1′ and the second conductive adhesive layer Ca2′ may be films formed by dispersing metal particles including a metal, for example, Au, Ag, Pt, or Ni, in a synthetic resin. The synthetic resin may include a material such as epoxy, silicone, PI, or polyurethane. However, one or more embodiments are not limited thereto.

The second portion PPCBa2 may be connected to the first portion PPCBa1, and the second portion PPCBa2 and the first portion PPCBa1 may include the same material as each other. In detail, the second portion PPCBa2 may be connected to the conductive nonwoven layer NWL′, and the second portion PPCBa2 and the conductive nonwoven layer NWL′ may include the same material as each other. That is, the second portion PPCBa2 may include a nonwoven fabric plated with a metal material such as Cu or Ni. That is, the second portion PPCBa2 may integrally formed as a single body with the conductive nonwoven layer NWL′ of the first portion PPCBa1.

In general, the conductive nonwoven layer NWL of the printed circuit board adhesive layer PCBa may be formed by cutting a fabric into a preset shape by using a cutting tool or the like, the fabric including a nonwoven fabric plated with a metal material. However, when the fabric is cut into the preset shape by using the cutting tool or the like, the fabric may not be accurately cut, and portions of the fabric, which need to be cut, may remain uncut. Alternatively, the fabric may be accurately cut into the preset shape such that threads that were present within the preset shape at the time of cutting may protrude to the outside of the preset shape in a subsequent process. That is, by-products generated by cutting, such as burrs, may be present on the outside of a conductive nonwoven fabric layer cut into a preset shape. The second portion PPCBa2 may be a by-product generated by the cutting. In other words, the second portion PPCBa2 may be a by-product generated by cutting the fabric into the shape of the conductive nonwoven layer NWL, the fabric including the nonwoven fabric plated with the metal material.

The release film RF may be attached to one surface of the printed circuit board PCB. In detail, the release film RF may be attached to the rear surface of the printed circuit board PCB through the release film adhesive layer RFa. That is, the release film adhesive layer RFa and the preliminary printed circuit board adhesive layer PPCBa may be attached to the same surface as each other. Accordingly, the release film adhesive layer RFa may be between the printed circuit board PCB and the release film RF. As described below, the printed circuit board PCB may be formed by the preliminary printed circuit board adhesive layer PPCBa. In other words, the release film adhesive layer RFa and the printed circuit board adhesive layer PCBa may be arranged on the same surface of the printed circuit board PCB.

The release film RF may be attached to the same surface as one surface of the printed circuit board PCB to which the printed circuit board adhesive layer PCBa is attached. In detail, the release film RF may cover the printed circuit board adhesive layer PCBa attached to the printed circuit board PCB and may also cover a portion of one surface of the printed circuit board PCB, to which the printed circuit board adhesive layer PCBa is not attached. Accordingly, the release film RF may protect the printed circuit board adhesive layer PCBa before being attached to the metal plate MP and may protect one surface of the printed circuit board PCB to which the release film RF is attached.

The release film RF may include a plastic film including polymer resin. In an embodiment, for example, the release film RF may include at least one of polymer resins such as PET, PBT, PC, PEN, PS, PMMA, PVC, PES, PP, or PA. In addition, the release film adhesive layer RFa may include an adhesive member such as an OCA or a PSA. Alternatively, the release film adhesive layer RFa may include a silicone-based adhesive or an acrylic adhesive. However, one or more embodiments are not limited thereto.

In a plan view, the release film adhesive layer RFa may be arranged to be spaced apart from the first portion PPCBa1. In detail, in a plan view, at least a portion of the release film adhesive layer RFa may be arranged along the outside of the first portion PPCBa1 to surround at least a portion of the first portion PPCBa1. The release film adhesive layer RFa may include a first release film adhesive layer RFa1 and a second release film adhesive layer RFa2. In a plan view, the first release film adhesive layer RFa1 and the second release film adhesive layer RFa2 may be arranged to face each other with the release film adhesive layer RFa therebetween. In an embodiment, for example, in a plan view, the first release film adhesive layer RFa1 may be arranged outside the closed loop formed by the printed circuit board adhesive layer PCBa, and the second release film adhesive layer RFa2 may be arranged inside the closed loop formed by the printed circuit board adhesive layer PCBa. However, one or more embodiments are not limited thereto.

As shown in FIG. 13, a portion of the release film adhesive layer RFa may be attached to a portion of the second portion PPCBa2. In other words, the second portion PPCBa2 may be attached to the release film RF through the release film adhesive layer RFa. Alternatively, the release film RF may be attached to the second portion PPCBa2 through the release film adhesive layer RFa. FIG. 13 shows that a portion of the second release film adhesive layer RFa2 is attached to a portion of the second portion PPCBa2, but one or more embodiments are not limited thereto. For another example, in a plan view, when the second portion PPCBa2 is arranged outside the closed loop formed by the printed circuit board adhesive layer PCBa, a portion of the first release film adhesive layer RFa1 may also be attached to a portion of the second portion PPCBa2.

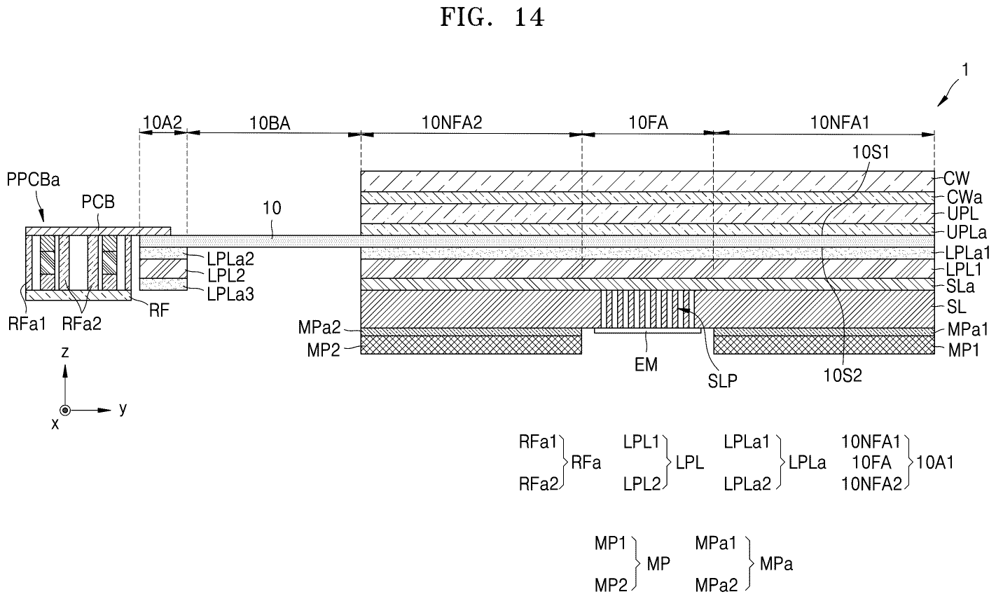

Next, as shown in FIG. 14, the printed circuit board PCB may be bonded to the second panel area 10A2. As described above, the pads of the display panel 10 may be arranged in the second panel area 10A2, and after the bumps of the printed circuit board PCB are disposed on the pads of the display panel 10, the bumps are attached to the pads, respectively, and thus, the printed circuit board PCB may be bonded to the second panel area 10A2. In general, the printed circuit board PCB may be attached to the display panel 10 by using a pressurizing apparatus. In detail, the bumps may be attached to the pads by arranging an anisotropic conductive film between the pads of the second panel area 10A2 and the bumps of the printed circuit board PCB, and applying a certain amount of heat and pressure to the top of the printed circuit board PCB by using a pressurizing apparatus such as a hot bar. The anisotropic conductive film may include a thermosetting resin and a conductive ball, and the thermosetting resin may be thermally cured when a certain amount of heat and pressure are applied to the top of the printed circuit board PCB.

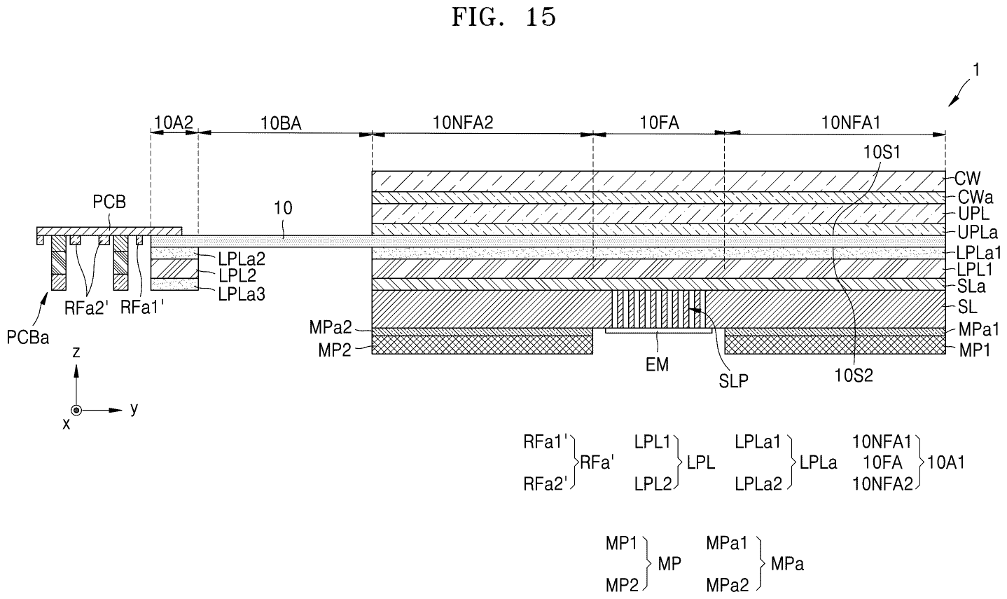

Next, as shown in FIG. 15, the release film RF may be removed from the printed circuit board PCB. Accordingly, the printed circuit board adhesive layer PCBa may be formed. In detail, the release film adhesive layer RFa may be attached to the release film RF, and the release film adhesive layer RFa may be attached to a portion of the second portion PPCBa2. That is, the release film RF may be attached to the second portion PPCBa2 through the release film adhesive layer RFa. In this case, the release film adhesive layer RFa may also be removed along with desorption of the release film RF. Also, the second portion PPCBa2 may also be removed along with removal of the release film adhesive layer RFa. Accordingly, because only the first portion PPCBa1 corresponding to the printed circuit board adhesive layer PCBa is present on the printed circuit board PCB, the printed circuit board adhesive layer PCBa may be formed. That is, the printed circuit board adhesive layer PCBa may be the preliminary printed circuit board adhesive layer PPCBa from which by-products are removed.

In addition, the residual adhesive layer RFa′ may be arranged on the rear surface of the printed circuit board PCB to which the release film adhesive layer RFa was attached. The residual adhesive layer RFa′ and the release film adhesive layer RFa may include the same material as each other. A portion of the release film adhesive layer RFa may remain on the rear surface of the printed circuit board PCB after the release film adhesive layer RFa is removed from the printed circuit board PCB. The residual adhesive layer RFa′ may be the portion of the release film adhesive layer RFa remaining on the rear surface of the printed circuit board PCB. Accordingly, the residual adhesive layer RFa′ may correspond to the release film adhesive layer RFa. In detail, the residual adhesive layer RFa′ may include the first residual adhesive layer RFa1′ and the second residual adhesive layer RFa2′, and the first residual adhesive layer RFa1′ and the second residual adhesive layer RFa2′ may correspond to the first release film adhesive layer RFa1 and the second release film adhesive layer RFa2, respectively. Therefore, a repeated description regarding this will be omitted.

In detail, the residual adhesive layer RFa′ may be arranged on the rear surface of the printed circuit board PCB in contact with the printed circuit board adhesive layer PCBa. In a plan view, the residual adhesive layer RFa′ may be arranged to be spaced apart from the printed circuit board adhesive layer PCBa. In a plan view, at least a portion of the residual adhesive layer RFa′ may be arranged along the outside of the printed circuit board adhesive layer PCBa to surround at least a portion of the printed circuit board adhesive layer PCBa.

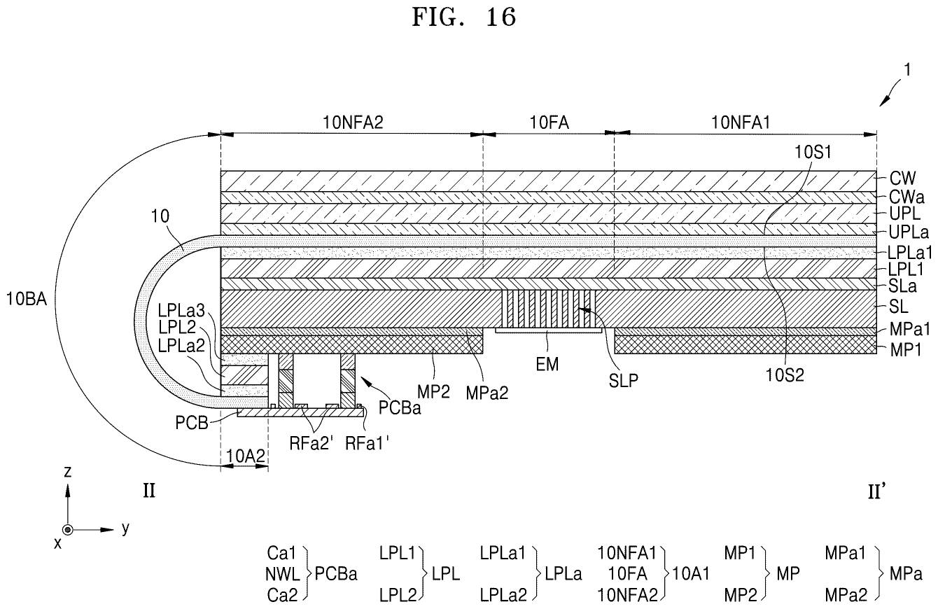

Next, as shown in FIG. 16, the printed circuit board PCB may be attached to the underside of the metal plate MP by bending the panel bending area 10BA. In detail, the printed circuit board PCB may be attached under the second metal plate MP2 by bending the panel bending area 10BA. That is, the printed circuit board PCB may be attached under the second metal plate MP2 by attaching the printed circuit board adhesive layer PCBa under the second metal plate MP2. In other words, the printed circuit board PCB may be attached under the second metal plate MP2 through the printed circuit board adhesive layer PCBa. In this case, the second panel area 10A2 may also be arranged under the second metal plate MP2. The second lower protective layer LPL2 attached to the second panel area 10A2 may be attached under the second metal plate MP2 through the third lower protective layer adhesive layer LPLa3. Accordingly, the second panel area 10A2 may be attached under the second metal plate MP2.

By-products protruding outside the printed circuit board adhesive layer PCBa may cause post-process defects and appearance defects. However, in the method of manufacturing the display apparatus according to the present embodiment, by-products protruding outside the printed circuit board adhesive layer PCBa are removed using the release film adhesive layer RFa, and thus, post-process defects and appearance defects caused by the by-products protruding outside the printed circuit board adhesive layer PCBa may be prevented or significantly reduced. Therefore, the possibility of occurrence of defects in a manufacturing process of the display apparatus 1 may be effectively reduced.

As described above, the disclosure has been described with reference to the one or more embodiments shown in the accompanying drawings, but should be considered in a descriptive sense only. Those of ordinary skill in the art will understand that various modifications and equivalent embodiments may be made therefrom. Therefore, the true technical scope of protection of the disclosure should be defined by the technical spirit of the appended claims.

According to embodiments of the disclosure as described above, a display apparatus with a reduced possibility of occurrence of defects in a manufacturing process and a method of manufacturing the display apparatus may be implemented. However, the scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display apparatus, the method comprising:
providing a display panel including a first panel area, a second panel area, and a panel bending area between the first panel area and the second panel area, wherein a metal plate is attached under the first panel area of the display panel;
providing a printed circuit board to which a preliminary printed circuit board adhesive layer and a release film are attached;
bonding the printed circuit board to the second panel area;
forming a printed circuit board adhesive layer by removing the release film from the printed circuit board; and
attaching the printed circuit board under the metal plate by bending the panel bending area,
wherein, in the providing of the printed circuit board, the release film is attached to the printed circuit board through a release film adhesive layer between the release film and the printed circuit board,
the preliminary printed circuit board adhesive layer includes a first portion and a second portion other than the first portion, the first portion corresponding to the printed circuit board adhesive layer, and
the release film adhesive layer is attached to the second portion.

2. The method of claim 1, wherein the forming of the printed circuit board adhesive layer comprises removing the release film adhesive layer from the printed circuit board by removing the release film from the printed circuit board.

3. The method of claim 2, wherein the forming of the printed circuit board adhesive layer further comprises, when the release film adhesive layer is removed from the printed circuit board, removing the second portion, which is attached to the release film adhesive layer.

4. The method of claim 1, wherein the first portion and the second portion include a same material as each other.

5. The method of claim 4, wherein the first portion includes a first conductive adhesive layer, a second conductive adhesive layer, and a conductive nonwoven layer between the first conductive adhesive layer and the second conductive adhesive layer, and
the second portion and the conductive nonwoven layer include a same material as each other.

6. The method of claim 5, wherein, in the providing of the printed circuit board, the first conductive adhesive layer of the preliminary printed circuit board adhesive layer is attached to the printed circuit board.

7. The method of claim 1, wherein, in the providing of the printed circuit board, the release film adhesive layer and the printed circuit board adhesive layer are arranged on a same surface of the printed circuit board.

8. The method of claim 1, wherein, in the providing of the printed circuit board, in a plan view, the release film adhesive layer is arranged to be spaced apart from the first portion.

9. The method of claim 1, wherein, in the providing of the printed circuit board, in a plan view, at least a portion of the release film adhesive layer is arranged along an outside of the first portion to surround at least a portion of the first portion.

10. The method of claim 1, wherein, in the providing of the printed circuit board, in a plan view, the preliminary printed circuit board adhesive layer is arranged along an outer portion of the printed circuit board to surround at least a portion of the printed circuit board.

11. The method of claim 1, wherein the attaching of the printed circuit board comprises attaching the printed circuit board adhesive layer under the metal plate.

12. A display apparatus comprising:
a display panel including a first panel area, a second panel area, and a panel bending area between the first panel area and the second panel area;
a metal plate arranged under the first panel area;
a printed circuit board bonded to the second panel area and arranged under the metal plate;
a printed circuit board adhesive layer between the printed circuit board and the metal plate; and
a residual adhesive layer arranged on one surface of the printed circuit board in contact with the printed circuit board adhesive layer,
wherein, in a plan view, the residual adhesive layer is arranged to be spaced apart from the printed circuit board adhesive layer.

13. The display apparatus of claim 12, wherein, in the plan view, at least a portion of the residual adhesive layer is arranged along an outside of the printed circuit board adhesive layer to surround at least a portion of the printed circuit board adhesive layer.

14. The display apparatus of claim 12, wherein, in the plan view, the printed circuit board adhesive layer is arranged along an outer portion of the printed circuit board to surround at least a portion of the printed circuit board.

15. The display apparatus of claim 12, wherein the first panel area includes a first non-folding area, a second non-folding area, and a foldable area between the first non-folding area and the second non-folding area, and
the display apparatus is foldable at the foldable area.

16. The display apparatus of claim 12, wherein the printed circuit board adhesive layer includes a first conductive adhesive layer, a second conductive adhesive layer, and a conductive nonwoven layer between the first conductive adhesive layer and the second conductive adhesive layer.

17. The display apparatus of claim 16, wherein the first conductive adhesive layer is between the printed circuit board and the conductive nonwoven layer, and
the second conductive adhesive layer is between the conductive nonwoven layer and the metal plate.

18. The display apparatus of claim 16, wherein the conductive nonwoven layer includes a void.

19. The display apparatus of claim 12, further comprising:
a lower protective layer arranged under the display panel; and
a support layer between the lower protective layer and the metal plate.

20. The display apparatus of claim 12, further comprising:
a cover window arranged over the display panel; and
an upper protective layer between the display panel and the cover window.
